(19) United States
(12) Patent Application Publication
(10) Pub. No.: US 2026/0019050 A1
(43) Pub. Date: Jan. 15, 2026

(54) COMPENSATED AMPLIFIER CIRCUIT

(71) Applicant: MACOM Technology Solutions Holdings, Inc., Lowell, MA (US)

(72) Inventor: Thomas Aaron Winslow, Salem, VA (US)

(21) Appl. No.: 18/770,182

(22) Filed: Jul. 11, 2024

(51) Int. Cl. H03F 3/24

(52) U.S. Cl. CPC H03F 3/245; H03F 2200/451

(57) ABSTRACT

Aspects of an amplifier with bias compensation are described. An example compensated amplifier circuit includes an output amplifier stage with an input terminal, a compensation circuit include a biasing leg, and a single supply voltage connection coupled at one end of the biasing leg. The biasing leg includes a stack of biasing transistors, a bias node along the stack of biasing transistors, and biasing resistors coupled among the stack of biasing transistors. The bias node of the compensation circuit is coupled to the input terminal of the output amplifier stage. The bias voltage that is generated at the bias node by the compensation circuit helps to compensate for variations in current density, process or threshold voltages, and temperature variations among different output amplifier stages.

### BACKGROUND

Transistors are commonly used as amplifiers or as parts of amplifier circuits. A transistor, such as a field-effect transistor (FET), can be configured as a certain type or class of amplifier based on which terminal of the transistor is common to both the input and the output of the transistor. For FETs, the amplifier classes include common source, common gate, and common drain. In the case of bipolar junction transistors, the amplifier classes include common emitter, common base, and common collector.

### SUMMARY

Certain aspects of the concepts and embodiments described herein are summarized below. The aspects are representative and not exhaustively listed. In alternate embodiments, certain features and elements can be added, omitted, and interchanged with each other. Additionally, variations, extensions, and modifications to the example embodiments can be achieved by those skilled in the art without departing from the concepts, so as to encompass equivalent and related structures.

Aspects of an amplifier with bias control and compensation are described. An example compensated amplifier circuit includes an output amplifier stage with an input terminal, a compensation circuit include a biasing leg, and a single supply voltage connection coupled at one end of the biasing leg. The biasing leg includes a stack of biasing transistors, a bias node along the stack of biasing transistors, and biasing resistors coupled among the stack of biasing transistors. The bias node of the compensation circuit is coupled to the input terminal of the output amplifier stage. The bias voltage that is generated at the bias node by the compensation circuit helps to compensate for variations in current density, process or threshold voltages, and temperature variations among different output amplifier stages.

The output amplifier stage includes a depletion mode transistor in some cases. The single supply voltage connection can be a connection for a negative voltage at the one end of the biasing leg for the generation of bias voltages for depletion mode transistors. For depletion mode transistors, the compensation circuit is configured to provide a negative bias voltage at the bias node for the output amplifier stage. In other aspects, the single supply voltage connection includes a connection for a negative voltage at the one end of the biasing leg, and the compensated amplifier circuit also includes a ground connection coupled at another end of the biasing leg.

In other aspects, the stack of biasing transistors includes a first biasing transistor and a second biasing transistor. A gate of the first biasing transistor is directly coupled to a drain of the second biasing transistor. A resistor among the biasing resistors is directly coupled between a source of the first biasing transistor and the gate of the first biasing transistor. The gate of the first biasing transistor is also directly coupled to a bond pad or a package terminal in some examples. A drain of the second biasing transistor is directly coupled to the gate of the first biasing transistor.

In still other aspects, a gate of the second biasing transistor is directly coupled to the single supply voltage connection, and a second resistor among the biasing resistors is directly coupled between a source of the second biasing transistor and the single supply voltage connection. The single supply voltage connection includes a bond pad or a package terminal in another example, and the gate of the second biasing transistor is directly coupled to the bond or the package terminal for the single supply voltage connection.

The biasing resistors also include a third biasing resistor coupled between a drain of the first biasing transistor and a bond pad or a package terminal in another example. The biasing resistors can also include a resistor divider coupled between a drain of the first biasing transistor and ground in another case. The resistor divider can be implemented as an on-chip resistor and an off-chip resistor.

The output amplifier stage can be embodied as a depletion mode power transistor. To support depletion mode power transistors, the single supply voltage connection can be a connection for or to a negative voltage at the one end of the biasing leg. The amplifier and compensation circuit can also include a ground connection coupled at another end of the biasing leg. The depletion mode power transistor can be a GaAs pHEMT transistor. The depletion mode power transistor can also be a GaN HEMT transistor.

Another compensated amplifier circuit includes a depletion mode power transistor and a compensation circuit. The compensation circuit includes a biasing leg. The biasing leg includes a stack of biasing transistors, a bias node along the stack of biasing transistors, and biasing resistors coupled among the stack of biasing transistors. The bias node of the compensation circuit is coupled to a gate terminal of the depletion mode power transistor.

The compensated amplifier circuit also includes a single supply voltage connection coupled at one end of the biasing leg and a ground connection coupled at another end of the biasing leg in some cases. The single supply voltage connection includes a connection for or to a negative voltage at the one end of the biasing leg, and the compensation circuit is configured to provide a negative bias voltage at the bias node for the depletion mode power transistor.

The stack of biasing transistors includes a first biasing transistor and a second biasing transistor. A gate of the first biasing transistor is directly coupled to a drain of the second biasing transistor, and a resistor among the biasing resistors is directly coupled between a source of the first biasing transistor and the gate of the first biasing transistor. A gate of the second biasing transistor is directly coupled to the single supply voltage connection, and a second resistor among the biasing resistors is directly coupled between a source of the second biasing transistor and the single supply voltage connection.

Another example compensated amplifier circuit includes a transistor, a compensation circuit with a biasing leg, and a single supply voltage connection coupled at one end of the biasing leg. The biasing leg includes a stack of biasing transistors, a bias node along the stack of biasing transistors coupled to a terminal of the transistor, and biasing resistors coupled among the stack of biasing transistors.

### BRIEF DESCRIPTION OF THE DRAWINGS

Aspects of the present disclosure can be better understood with reference to the following drawings. It is noted that the elements in the drawings are not necessarily drawn to scale, with emphasis instead being placed upon illustrating the principles of the examples. In the drawings, like reference numerals designate like or corresponding, but not necessarily the same, elements throughout the several views.

FIG. 1 illustrates an example compensated amplifier circuit according to various examples described herein.

FIG. 2 illustrates another example compensated amplifier circuit according to various examples described herein.

FIG. 3 illustrates another example compensated amplifier circuit according to various examples described herein.

FIG. 4 illustrates another example compensated amplifier circuit according to various examples described herein.

### DETAILED DESCRIPTION

The design of an amplifier includes the evaluation of a number of operating characteristics of the amplifier, such as amplifier biasing and bias current density, gain, operating bandwidth, small signal parameters, stability, and other input and output operating characteristics. The design of an amplifier also typically includes the evaluation of operating characteristics over process and operating temperature variations. Amplifier biasing can be relied upon to tailor the operating characteristics of amplifiers to some extent. Amplifier biasing can be relied upon to compensate for variations in bias current and bias current density among different transistors that are all manufactured using the same process techniques.

Compensation circuits are often relied upon to generate and adjust bias voltages provided to amplifier stages. The bias voltages can help to compensate for variations in current density, process or threshold voltages, temperature variations among different amplifiers, and other concerns. Compensation circuits can achieve a reduced standard deviation of the quiescent operating current of a transistor within an amplifier against the process induced variability in the threshold voltages, current densities, and other operating characteristics among individual power transistors manufactured using the same process.

Aspects of an amplifier with bias compensation are described. An example compensated amplifier circuit includes an output amplifier stage with an input terminal, a compensation circuit include a biasing leg, and a single supply voltage connection coupled at one end of the biasing leg. The biasing leg includes a stack of biasing transistors, a bias node along the stack of biasing transistors, and biasing resistors coupled among the stack of biasing transistors. The bias node of the compensation circuit is coupled to the input terminal of the output amplifier stage. The bias voltage that is generated at the bias node by the compensation circuit helps to compensate for process induced variations in current density, process or threshold voltages, and temperature variations among different output amplifier stages.

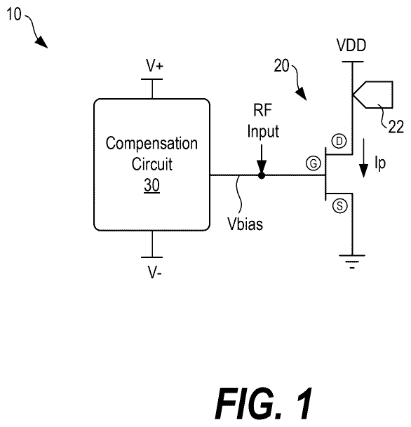

FIG. 1 illustrates an example compensated amplifier circuit 10 (also “amplifier circuit 10”) according to various examples described herein. The amplifier circuit 10 can be embodied in various ways, such as using discrete components, as an integrated circuit device formed on a substrate, or as a combination of discrete components and integrated devices. The amplifier circuit 10 is provided as a representative example of an output amplifier stage with a compensation circuit. The amplifier circuit 10 is not exhaustively illustrated in FIG. 1, and the amplifier circuit 10 can include additional components that are not shown.

The amplifier circuit 10 includes an output amplifier stage 20 (also “output amplifier 20”) and a compensation circuit 30 among possibly other components. The output amplifier 20 can be used as an output or driver amplifier for radio frequency (RF) communications, for optical communications, or for other purposes, without limitation. The compensation circuit 30 includes circuitry for generating a gate bias voltage for the output amplifier 20, as described in further detail below, and the output amplifier 20 is provided as an example of an output amplifier that can rely upon the bias compensation and stabilization concepts described herein. Other types and configurations of amplifiers and amplifier circuits can also incorporate and rely upon the bias compensation and stabilization concepts.

The output amplifier 20 can be embodied as power transistor, such as a FET transistor formed in gallium arsenide (GaAs), gallium nitride (GaN), GaN materials, or other semiconductor materials on a substrate. In more particular examples, the output amplifier 20 can be embodied as a depletion mode FET transistor, such as a depletion mode GaAs pseudomorphic high-electron mobility transistor (pHEMT) transistor, a GaN HEMT transistor, a GaN materials HEMT transistor, or a related power transistor. The output amplifier 20 can be structured as a metal-semiconductor field-effect transistor (MESFET), as one example, although other types of transistors can be relied upon.

The output amplifier 20 is coupled between a supply voltage VDD and ground. Particularly, the drain of the output amplifier 20 is coupled to the supply voltage VDD, and the source of the output amplifier 20 is coupled to ground. Any suitable supply voltage VDD can be relied upon. Supply voltages within the ranges of 5-20V, 10-30V, 20-50V, 30V-70V, 40V-90V, 50V-120V, 70V-150V, or larger ranges are within the scope of the embodiments. Example VDD voltages include 10V, 20V, 30V, 40V, 50V, 60V, 70V, 80V, 90V, 100V, 110V, 120V, 130V, 140V, and 150V, and other VDD voltages can be relied upon.

The output amplifier 20 is arranged as a single-ended common source power amplifier, with a radio frequency (RF) input applied at the gate terminal of the output amplifier 20 and an output 22 taken from the drain terminal of the output amplifier 20. In some cases, one or more biasing resistors can be electrically coupled between the supply voltage VDD and the drain terminal of the output amplifier 20. One or more biasing resistors can also be electrically coupled between the source terminal of the output amplifier 20 and ground in some cases.

The compensation circuit 30 is operated between source and sink voltages or potentials V+ and V−, respectively. The source voltage V+ can be any suitable voltage, and the sink voltage V− can be any suitable voltage or potential (e.g., including ground potential in some cases) that is less than the source voltage V+. The source and sink voltages V+ and V− can be selected, respectively, based on the target biasing voltage or voltage range for the output amplifier 20. The difference in potential between the source voltage V+ and the sink voltage V− can be any suitable potential difference based on the target biasing voltage or voltage range for the output amplifier 20.

The compensation circuit 30 can include a biasing leg in at least one embodiment, as described in further detail below. The biasing leg can include a stack of biasing transistors, a bias node along the stack of biasing transistors, and biasing resistors coupled among the stack of biasing transistors. The bias node of the compensation circuit 30 is coupled to the gate or input terminal of the output amplifier 20. The amount of current Ip through the output amplifier 20 is in large part a function of the bias voltage potential Vbias at the gate of the output amplifier 20, which is supplied by the compensation circuit 30. Even a minor change in the potential of Vbias at the gate of the output amplifier 20 can result in a significant variation in the current Ip, particularly when the output amplifier 20 is operating in the active region.

Compensation circuits can be relied upon to generate and adjust bias voltages provided to amplifier stages. The bias voltages can help to compensate for variations in current density, process or threshold voltages, temperature variations among different amplifiers, and other concerns. Compensation circuits can achieve a reduced standard deviation in the operating quiescent current of an amplifier due to process related variations in threshold voltages, current densities, and other operating characteristics among individual power transistors manufactured using the same process.

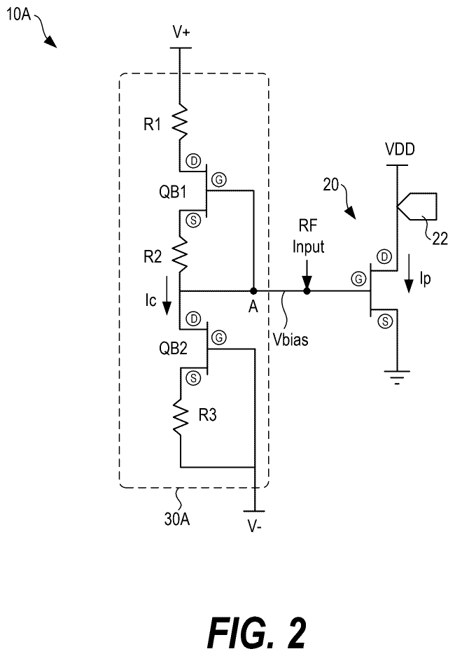

FIG. 2 illustrates another example compensated amplifier circuit 10A (also “amplifier circuit 10A”) according to various examples described herein. The amplifier circuit 10A can be embodied in various ways, such as using discrete components, as an integrated circuit device formed on a substrate, or as a combination of discrete components and integrated devices. The amplifier circuit 10A is provided as a representative example of an output amplifier stage with a compensation circuit. The amplifier circuit 10A is not exhaustively illustrated in FIG. 2, and the amplifier circuit 10A can include additional components that are not shown.

The amplifier circuit 10A includes the output amplifier 20 and a compensation circuit 30A among possibly other components. The output amplifier 20 is coupled between the supply voltage VDD and ground. The output amplifier 20 is arranged as a single-ended common source power amplifier, with an RF input applied at the gate terminal of the output amplifier 20 and an output 22 taken from the drain terminal of the output amplifier 20.

As in FIG. 1, the output amplifier 20 can be embodied as a GaAs, GaN, GaN materials, or related power FET transistor. In more particular examples, the output amplifier 20 can be embodied as a GaAs pHEMT, a GaN HEMT, a GaN materials HEMT, or a related depletion mode power FET transistor. The output amplifier 20 can be structured as MESFET, as one example, although other types of transistors can be relied upon.

The compensation circuit 30A includes a number of transistors and resistors in the example depicted. The compensation circuit 30A includes a biasing leg. The biasing leg is coupled between the source and sink voltages or potentials V+ and V−. The biasing leg generates a bias voltage potential Vbias, which is coupled to the gate of the output amplifier 20. The bias voltage potential Vbias is established and generated based on voltage drops between the source and sink voltages V+ and V− along the biasing leg, taken at a particular node “A” along the biasing leg.

The biasing leg includes a stack of biasing transistors QB1 and QB2, a bias node A between the biasing transistors QB1 and QB2, and biasing resistors R1, R2, and R3 coupled among the biasing transistors QB1 and QB2. The bias node A of the compensation circuit 30 is coupled to the gate or input terminal of the output amplifier 20. The compensation circuit 30A generates the bias voltage potential Vbias at the bias node A. The current Ip through the output amplifier 20 is in large part a function of the bias voltage potential Vbias at the bias node A, which is coupled to the gate of the output amplifier 20. Even a minor change in the potential of Vbias at the gate of the output amplifier 20 can result in a significant variation in the current Ip, particularly when the output amplifier 20 is operating in the active region.

The compensation circuit 30A is operated between the source and sink voltages V+ and V−. The source voltage V+ can be any suitable voltage, and the sink voltage V− can be any suitable voltage or potential (e.g., including ground potential in some cases) that is less than the source voltage V+. The source and sink voltages V+ and V− can be selected, respectively, based on the target Vbias voltage or voltage range.

The target Vbias voltage or voltage range for the output amplifier 20 can depend on the type of the output amplifier 20, including the semiconductor materials and process used to manufacture the output amplifier 20, the structure or type of the output amplifier 20 (e.g., MOSFET, MISFET, MESFET, pHEMT, HEMT, use of field plates, etc.), and related considerations. The target Vbias voltage or voltage range for the output amplifier 20 can also depend on the particular use case for amplification.

The drain terminal of QB1 is coupled to one end of R1, and the other end of R1 is coupled to V+. The gate terminal of QB1 is coupled to the drain terminal of QB2. The resistor R2 is coupled between the source terminal of QB1 and the gate terminal of QB1. In the particular example depicted, the gate terminal of QB1 is directly coupled to the drain terminal of QB2, and the resistor R2 is directly coupled between the source terminal of QB1 and the gate terminal of QB1.

The drain terminal of QB2 is coupled to one end of R2 and to the gate terminal of QB1. The gate terminal of QB2 is coupled to V−. The source terminal of QB2 is coupled to one end of R3, and the other end of R3 is coupled to V−. In the particular example depicted, the drain terminal of QB2 is directly coupled to one end of R2 and directly coupled to the gate terminal of QB1. The gate terminal of QB2 is directly coupled to V−. The source terminal of QB2 is directly coupled to one end of R3, and the other end of R3 is directly coupled to V−.

The biasing transistors QB1 and QB2 can be embodied as GaAs, GaN, GaN materials, or related power FET transistors. In a more particular example, the biasing transistors QB1 and QB2 can be embodied as GaAs pHEMTs, GaN HEMTs, GaN materials HEMTs, or related depletion mode power FET transistors. The transistors QB1 and QB2 and the output amplifier 20 can all be embodied as depletion mode n-channel GaAs pHEMT, GaN HEMT, or GaN materials HEMT transistors. The transistors QB1 and QB2, the resistors R1-R3, and the output amplifier 20 can be manufactured together in the same type(s) of semiconductor materials on the same semiconductor substrate in a preferred embodiment.

The sizes (e.g., channel width, channel length, etc.) of the biasing transistors QB1 and QB2 can be selected based on the size of the output amplifier 20, and the sizes can be optimized based on the application or use case. The biasing transistors QB1 and QB2 can be large enough to support the charge needed for maintenance of the Vbias potential at the gate terminal of the output amplifier 20. An aspect ratio of 10:1 is an example sizing ratio between the output amplifier 20 (i.e., relative size of 10) and the biasing transistors QB1 and QB2 (i.e., relative size of 1). The aspect ratio can be optimized, and other aspect ratios can be relied upon. The biasing transistors QB1 and QB2 can be the same size, or the biasing transistors QB1 and QB2 can be different sizes. In one example, the size of QB1 is about ten times the size of QB2, but the relative sizes of the biasing transistors QB1 and QB2 can be optimized.

The compensation circuit 30A is designed to generate the Vbias voltage at the node A, which is provided to the gate of the output amplifier 20. The Vbias voltage can vary to some extent over time during operation of the amplifier circuit 10A, such as with changes in the operating temperature of the output amplifier 20, for example, among other operating characteristics. The generation of and changes in the Vbias voltage help to compensate for variations in current density, process or threshold voltages, and temperature variations that may otherwise occur among the output amplifier 20 and other amplifiers similar to the output amplifier 20. In other words, among a larger number of amplifier circuits similar to the amplifier circuit 10A, the compensation circuit 30A and similar compensation circuits can achieve a reduced standard deviation in the operating characteristics (e.g., threshold voltages, current densities, etc.) among the output amplifier 20 and similar output amplifiers.

The conductive channel of the output amplifier 20 can be predefined (i.e., normally on) without the application of any gate voltage, because the output amplifier 20 is a depletion mode transistor. Thus, it is not necessary to apply a minimum threshold voltage to the output amplifier 20 for the current Ip to flow through it, provided VDD is greater than zero. The current Ip through output amplifier 20 can be pinched off with the application of a negative gate voltage of sufficient potential, with reference to the source voltage, or a negative Vgs. The linear operating mode of the output amplifier 20 can also be achieved with a negative Vgs applied to it. Thus, with the output amplifier 20 embodied as a depletion mode transistor, the compensation circuit 30A may be designed to establish a negative Vbias voltage for operating the output amplifier 20. The compensation circuit 30A can be designed to establish a target Vbias voltage for operating the output amplifier 20 in the linear mode of operation for many amplification use cases and applications. It is not necessary to design the compensation circuit 30A to establish a target Vbias voltage for the linear operating mode of the output amplifier 20, however. The source and sink voltages V+ and V− and R1-R3 resistances can be selected to achieve a suitable negative Vbias voltage, as also described in further detail below.

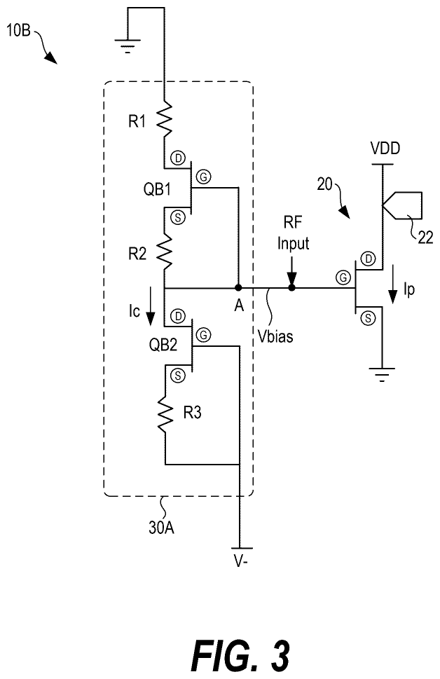

FIG. 3 illustrates another example compensated amplifier circuit 10B (also “amplifier circuit 10B”) according to various examples described herein. The amplifier circuit 10B is provided as a representative example of an output amplifier stage with a compensation circuit. The amplifier circuit 10B is not exhaustively illustrated in FIG. 3, and the amplifier circuit 10B can include additional components that are not shown.

The amplifier circuit 10B includes the output amplifier 20 and the compensation circuit 30A among possibly other components. The output amplifier 20 is coupled between the supply voltage VDD and ground. The output amplifier 20 is arranged as a single-ended common source power amplifier, with an RF input applied at the gate terminal of the output amplifier 20 and an output 22 taken from the drain terminal of the output amplifier 20.

The compensation circuit 30A shown in FIG. 3 is similar to that shown in FIG. 2. In contrast to FIG. 2, however, the biasing leg is not coupled between the source and sink voltages V+ and V−. Instead, the biasing leg of the compensation circuit 30A is coupled between ground and the sink voltage V− in FIG. 3. The compensation circuit 30A relies upon only a single supply voltage connection at one end of the biasing leg, and it is coupled to the sink voltage V−. The drain terminal of QB1 is coupled to one end of R1, and the other end of R1 is coupled to circuit ground. The source terminal of QB2 is coupled to one end of R3, and the other end of R3 is coupled to the sink voltage V−. Thus, only a single supply voltage connection, particularly the sink voltage V−, is coupled to the compensation circuit 30A. Ground potential and the coupling to ground is not considered a supply voltage connection, as would be understood in the field. The sink voltage V− can be any suitable voltage or potential less than the circuit ground potential. The sink voltage V− can be selected based on the target Vbias voltage or voltage range for the output amplifier 20, in connection with the design of the other components of the compensation circuit 30A. An example sink voltage V− is −3.3V, and other negative voltages can be relied upon.

The target Vbias voltage or voltage range for the output amplifier 20 can depend on the type of the output amplifier 20, including the semiconductor materials and process used to manufacture the output amplifier 20, the structure or type of the output amplifier 20 (e.g., MOSFET, MISFET, MESFET, pHEMT, HEMT, use of field plates, etc.), and related considerations. The target Vbias voltage or voltage range for the output amplifier 20 can also depend on the particular use case for amplification.

The compensation circuit 30A establishes a negative Vbias voltage for operating the output amplifier 20. The sink voltage V− and R1-R3 resistances can be selected and optimized to achieve a target Vbias voltage. The R1-R3 resistances (and the total resistance of the biasing leg) can be evaluated as a type of resistor voltage divider in the biasing leg of the compensation circuit 30A, along with the QB1 and QB2 transistors positioned between the R1-R3 resistances. The voltage drops across the resistances R2 and R3, respectively, establish the Vgs voltages across the QB1 and QB2 transistors. Thus, the resistances of R2 and R3 can be selected to achieve a voltage drop across each of them, respectively, sufficient to turn the QB1 and QB2 transistors on. The particular resistances of R2 and R3 can be selected and optimized for the target Vbias voltage at the node A, the application or use case for the output amplifier 20, and related considerations. The resistance R1 can also be selected and optimized accordingly for the target Vbias voltage at the node A. In one example, the resistance R2 can be selected to place QB1 into the saturated region or mode of operation, and the resistance R3 can be selected to place QB2 into the linear region or mode of operation. R3 is a relatively larger resistance than R2 in that case.

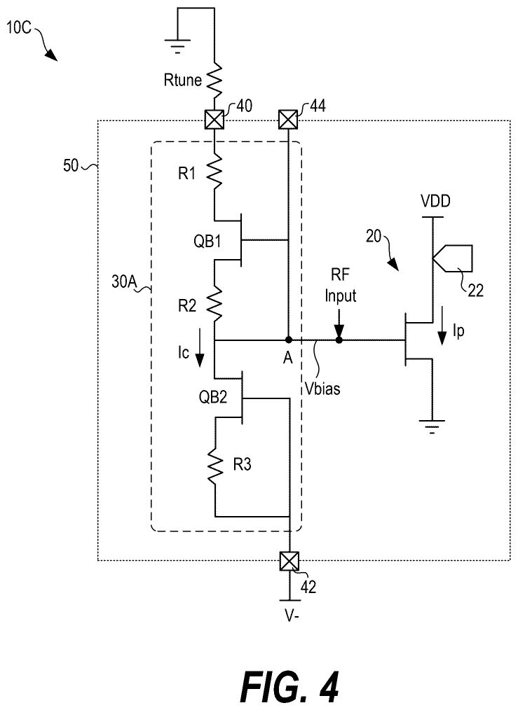

FIG. 4 illustrates another example compensated amplifier circuit 10C (also “amplifier circuit 10C”) according to various examples described herein. The amplifier circuit 10C is provided as a representative example of an output amplifier stage with a compensation circuit. The amplifier circuit 10C is not exhaustively illustrated in FIG. 4, and the amplifier circuit 10C can include additional components that are not shown.

The amplifier circuit 10C includes the output amplifier 20 and the compensation circuit 30A among possibly other components. The output amplifier 20 is coupled between the supply voltage VDD and ground. The output amplifier 20 is arranged as a single-ended common source power amplifier, with an RF input applied at the gate terminal of the output amplifier 20 and an output 22 taken from the drain terminal of the output amplifier 20.

The compensation circuit 30A shown in FIG. 4 is similar to that shown in FIG. 3. However, the compensation circuit 30A is coupled among the bond pad or package terminals 40, 42, and 44 (also “terminals 40, 42, and 44”) in FIG. 4. The terminals 40, 42, and 44 can be embodied as bond pads on a semiconductor substrate, terminal leads of a device package 50, wire bonds coupled between the bond pads and the terminal leads, or some combination thereof. The terminals 40, 42, and 44 are representative of electrical leads or terminals of a device package 50 as depicted in FIG. 4.

The compensation circuit 30A shown in FIG. 4 again relies upon only a single supply voltage connection at one end of the biasing leg, and it is coupled to the sink voltage V−. The drain terminal of QB1 is coupled to one end of R1, and the other end of R1 is coupled to the terminal 40. An additional tuning resistor Rtune is coupled between the terminal 40 and circuit ground. The Rtune resistor is an additional resistance in the bias leg according to the example shown in FIG. 4. The bias leg of the compensation circuit 30A includes the biasing resistors R1, R2, and R3, which are on-chip or on-substrate resistors. The bias leg of the compensation circuit 30A also includes the tuning resistor Rtune, which is an additional biasing resistor. The tuning resistor Rtune is an off-chip or off-substrate resistor, and Rtune can be selected separately from (and after) the values of R1, R2, and R3 are determined. The biasing resistors of the compensation circuit 30A thus include a resistor divider coupled between a drain of QB1 and ground. The resistor divider includes the on-chip R1 and the off-chip Rtune resistances.

The source terminal of QB2 is coupled to one end of R3, and the other end of R3 is coupled to the terminal 42. The terminal 42 is coupled to the sink voltage V−. Only a single supply voltage is coupled to the compensation circuit 30A in the example shown in FIG. 4. Particularly the sink voltage V− is coupled to the terminal 42. Ground potential and the coupling to ground is not considered a supply voltage connection, as would be understood in the field. The sink voltage V− can be any suitable voltage or potential less than the circuit ground potential. The sink voltage V− can be selected based on the target Vbias voltage or voltage range for the output amplifier 20.

The compensation circuit 30A can be designed to establish a negative Vbias voltage for operating the output amplifier 20 in the linear mode of operation in one example. It is not necessary to design the compensation circuit 30A to establish a target Vbias voltage for the linear operating mode of the output amplifier 20, however. Overall, the sink voltage V−, R1-R3 resistances, and Rtune resistance, can be selected to achieve a target Vbias voltage. The R1-R3 and Rtune resistances (and the total resistance of the biasing leg) can be evaluated as a type of resistor voltage divider in the biasing leg of the compensation circuit 30A, along with the QB1 and QB2 transistors positioned between the R1-R3 resistances. The voltage drops across the resistances R2 and R3, respectively, establish the Vgs voltages across the QB1 and QB2 transistors. Thus, the resistances of R2 and R3 can be selected to achieve a voltage drop across each of them, respectively, sufficient to turn the QB1 and QB2 transistors on. The particular resistances of R2 and R3 can be selected and optimized for the target Vbias voltage at the node A, the application or use case for the output amplifier 20, and related considerations. The resistances R1 and Rtune can also be selected and optimized accordingly for the target Vbias voltage at the node A. In one example, the resistance R2 can be selected to place QB1 into the saturated region or mode of operation, and the resistance R3 can be selected to place QB2 into the linear region or mode of operation. R3 is a relatively larger resistance than R2 in that case.

FIG. 4 also illustrates that the node A is electrically coupled to the terminal 44. The terminal 44 provides direct access to the potential at the node A and also the gate or input terminal of the output amplifier 20. The compensation circuit 30A can be effectively removed or disconnected from the output amplifier 20 in the arrangement shown in FIG. 4. Particularly, the terminals 40 and 42 can be left unconnected/floating. In that case, the compensation circuit 30A will not generate a Vbias voltage. A bias voltage can instead be coupled to the terminal 44 in that case. The terminals 40, 42, and 44 and connections among the compensation circuit 30A and the terminals 40, 42, and 44 offers additional flexibility and opportunities for testing and evaluation of the amplifier circuit 10C.

The compensated amplifier circuits 10, 10A, 10B, and 10C can be formed using any suitable semiconductor manufacturing process when integrated together on a single substrate. In other embodiments, the amplifier circuits 10, 10A, 10B, and 10C can be simulated on one or more computing devices using one or more circuit simulator, semiconductor device modeling, semiconductor process simulation, or related Technology Computer Aided Design (TCAD) software tools. The design and operating aspects of the amplifier circuits 10, 10A, 10B, and 10C can be simulated and tailored based on simulation, including the resistances of R1-R3, the sizes of the QB1 and QB2, the size of the output amplifier 20, the target Vbias voltage, other voltage and current biases, and other aspects. Simulations can be relied upon to model the characteristics and performance of the semiconductor devices (e.g., transistors) and other elements (e.g., resistors, inductors, capacitors, etc.) of the amplifier circuits 10, 10A, 10B, and 10C.

The amplifier circuits 10, 10A, 10B, and 10C described herein, among others consistent with the concepts described herein, can be embodied in hardware or simulated as a number of circuit elements in software. When simulated using software, each circuit element can be embodied as a module or listing of code associated with certain parameters to simulate the element. The software to simulate the circuit elements can include program instructions embodied in the form of, for example, source code that includes human-readable statements written in a programming language or machine code that includes machine instructions recognizable by a suitable execution system, such as a processor in a computer system or other system. If embodied in hardware, each element can represent a circuit or a number of electrically interconnected circuits.

One or more computing devices can execute the software to simulate the circuit elements that form the amplifiers described herein, among others. The computing devices can include at least one processing circuit. Such a processing circuit can include, for example, one or more processors and one or more storage or memory devices coupled to a local interface. The local interface can include, for example, a data bus with an accompanying address/control bus or any other suitable bus structure.

The storage or memory devices can store data or components that are executable by the processors of the processing circuit. For example, data associated with one or more circuit elements of the distributed amplifiers can be stored in one or more storage devices and referenced for processing by one or more processors in the computing devices. Similarly, the software to simulate the circuit elements and/or other components can be stored in one or more storage devices and be executable by one or more processors in the computing devices.

The transistors and other active devices described herein can be formed using group III-V semiconductor materials and semiconductor manufacturing processes. The group III elemental materials include scandium (Sc), aluminum (Al), gallium (Ga), and indium (In), and the group V elemental materials include nitrogen (N), phosphorus (P), arsenic (As), and antimony (Sb)). Thus, in some examples, the concepts can be applied to group III-V active semiconductor devices, such as the III-Nitrides (aluminum (Al)-, gallium (Ga)-, indium (In)-, and alloys (AlGaIn)-based Nitrides), GaAs, InP, InGaP, AlGaAs, etc. devices. However, the concepts may be applied to transistors and other active devices formed from other semiconductor materials.

The concepts described herein can be embodied by GaN-on-Si transistors and devices, GaN-on-SiC transistors and devices, as well as other types of semiconductor materials. As used herein, the phrase “gallium nitride material(s)” or “GaN material(s)” refers to gallium nitride and any of its alloys, such as aluminum gallium nitride (AlₓGa₍₁₋ₓ₎N), indium gallium nitride (In_{y}Ga_{(1-y)}N), aluminum indium gallium nitride (AlₓIn_{y}Ga_{(1-x-y)}N), gallium arsenide phosphide nitride (GaAsₐP_{b}N_{(1-a-b)}), aluminum indium gallium arsenide phosphide nitride (AlₓIn_{y}Ga_{(1-x-y)}ASₐP_{b}N_{(1-a-b)}), among others. Typically, when present, arsenic and/or phosphorous are at low concentrations (e.g., less than 5 weight percent). The gallium nitride materials can be n-type doped, p-type doped, or unintentionally doped (UID).

In embodiments with high concentrations of gallium, gallium nitride material has a high concentration of gallium and includes little or no aluminum or indium. In high gallium concentration embodiments, the sum of (x+y) may be less than 0.4 in some cases, less than 0.2 in some cases, less than 0.1 in some cases, or even less in other cases. The term “gallium nitride” or “GaN” refers directly to gallium nitride, exclusive of its alloys (i.e., x=y=a=b=0). The GaN can be n-type doped, p-type doped, or unintentionally doped (UID).

The transistors described herein can be formed as field effect transistors (FETs), although the concepts can be applied to other types of transistors. Among other types of FET transistors, the transistors described herein can be formed as high-electron mobility transistors (HEMTs), pseudomorphic high-electron mobility transistors (pHEMTs), metamorphic high-electron mobility transistors (mHEMTs), and other types of transistors. The FETs can include metal oxide or insulator semiconductor (MOSFET or MISFET) transistors and metal-semiconductor field-effect transistor (MESFETs). The transistors can include one or more field plates, such as source-connected field plates, gate-connected field plates, or both source-connected and gate-connected field plates.

In view of the limitations of the semiconductor manufacturing and processing techniques available in the field, the terms “approximately” and “about” reflect a certain inability (or uncertainty) to precisely control the exact dimensions of certain features described herein. Depending on the level of precision that can be achieved using the commercially-available semiconductor processing tools available at the time, the terms “approximately” and “about” may be used to mean within ±20% of a target value for some features, within ±10% of a target value for some features, within ±5% of a target value for some features, and within ±2% of a target value for some features. The terms “approximately” and “about” may include the target value.

The concepts described herein can be combined in one or more embodiments in any suitable manner, and the features discussed in the embodiments are interchangeable in some cases. Example embodiments are described herein, although a person of skill in the art will appreciate that the technical solutions and concepts can be practiced in some cases without all of the specific details of each example. Additionally, substitute or equivalent steps, components, materials, and the like may be employed. It should also be appreciated that some well-known process steps, semiconductor material layers, semiconductor device features, and other features have been omitted to avoid obscuring the concepts.

Although relative terms such as “on,” “below,” “upper,” “lower,” “top,” “bottom,” “right,” and “left” may be used to describe the relative spatial relationships of certain structural features, these terms are used for convenience only, as a direction in the examples. Thus, if a structure is turned upside down, the “upper” component will become a “lower” component. When a structure or feature is described as being “on” (or formed on) another structure or feature, the structure can be positioned directly on (i.e., contacting) the other structure, without any other structures or features intervening between the structure and the other structure. When a structure or feature is described as being “over” (or formed over) another structure or feature, the structure can be positioned over the other structure, with or without other structures or features intervening between them. When two components are described as being “coupled to” each other, the components can be electrically coupled to each other, with or without other components being electrically coupled and intervening between them. When two components are described as being “directly coupled to” each other, the components can be electrically coupled to each other, without other components being electrically coupled between them.

Terms such as “a,” “an,” “the,” and “said” are used to indicate the presence of one or more elements and components. The terms “comprise,” “include,” “have,” “contain,” and their variants are used to be open ended and may include or encompass additional elements, components, etc., in addition to the listed elements, components, etc., unless otherwise specified. The terms “first,” “second,” etc. may be used as differentiating identifiers of individual or respective components among a group thereof, rather than as a descriptor of a number of the components, unless clearly indicated otherwise.

Although embodiments have been described herein in detail, the descriptions are by way of example. The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be accorded the broadest interpretation so as to encompass modifications and equivalent structures.

Therefore, the following is claimed:

1. A compensated amplifier circuit comprising:
an output amplifier stage comprising an input terminal;
a compensation circuit comprising a biasing leg, the biasing leg comprising a stack of biasing transistors, a bias node along the stack of biasing transistors, and biasing resistors coupled among the stack of biasing transistors; and
a single supply voltage connection coupled at one end of the biasing leg, wherein:
the bias node of the compensation circuit is coupled to the input terminal of the output amplifier stage.

2. The compensated amplifier circuit according to claim 1, wherein:
the single supply voltage connection comprises a connection for a negative voltage at the one end of the biasing leg; and
the compensated amplifier circuit further comprises a ground connection coupled at another end of the biasing leg.

3. The compensated amplifier circuit according to claim 1, wherein:
the output amplifier stage comprises a depletion mode transistor;
the single supply voltage connection comprises a connection for a negative voltage at the one end of the biasing leg; and
the compensation circuit is configured to provide a negative bias voltage at the bias node for the output amplifier stage.

4. The compensated amplifier circuit according to claim 1, wherein:
the stack of biasing transistors comprises a first biasing transistor and a second biasing transistor;
a gate of the first biasing transistor is directly coupled to a drain of the second biasing transistor; and
a resistor among the biasing resistors is directly coupled between a source of the first biasing transistor and the gate of the first biasing transistor.

5. The compensated amplifier circuit according to claim 4, wherein the gate of the first biasing transistor is also directly coupled to a bond pad or a package terminal.

6. The compensated amplifier circuit according to claim 4, wherein a drain of the second biasing transistor is directly coupled to the gate of the first biasing transistor.

7. The compensated amplifier circuit according to claim 6, wherein:
a gate of the second biasing transistor is directly coupled to the single supply voltage connection; and
a second resistor among the biasing resistors is directly coupled between a source of the second biasing transistor and the single supply voltage connection.

8. The compensated amplifier circuit according to claim 6, wherein:
the single supply voltage connection comprises a bond pad or a package terminal, and
the gate of the second biasing transistor is directly coupled to the bond or the package terminal for the single supply voltage connection.

9. The compensated amplifier circuit according to claim 6, wherein the biasing resistors further comprises a third biasing resistor coupled between a drain of the first biasing transistor and ground.

10. The compensated amplifier circuit according to claim 6, wherein the biasing resistors further comprises a third biasing resistor coupled between a drain of the first biasing transistor and a bond pad or a package terminal.

11. The compensated amplifier circuit according to claim 6, wherein the biasing resistors further comprises a resistor divider coupled between a drain of the first biasing transistor and ground.

12. The compensated amplifier circuit according to claim 11, wherein the resistor divider comprises an on-chip resistor and an off-chip resistor.

13. The compensated amplifier circuit according to claim 1, wherein:
the output amplifier stage comprises a depletion mode power transistor;
the single supply voltage connection comprises a connection for a negative voltage at the one end of the biasing leg; and
the amplifier and compensation circuit further comprises a ground connection coupled at another end of the biasing leg.

14. A compensated amplifier circuit comprising:
a depletion mode power transistor; and
a compensation circuit comprising a biasing leg, the biasing leg comprising a stack of biasing transistors, a bias node along the stack of biasing transistors, and biasing resistors coupled among the stack of biasing transistors, wherein:
the bias node of the compensation circuit is coupled to a gate terminal of the depletion mode power transistor.

15. The compensated amplifier circuit according to claim 14, further comprising:
a single supply voltage connection coupled at one end of the biasing leg; and
a ground connection coupled at another end of the biasing leg.

16. The compensated amplifier circuit according to claim 15, wherein:
the single supply voltage connection comprises a connection for a negative voltage at the one end of the biasing leg; and
the compensation circuit is configured to provide a negative bias voltage at the bias node for the depletion mode power transistor.

17. The compensated amplifier circuit according to claim 15, wherein:
the stack of biasing transistors comprises a first biasing transistor and a second biasing transistor;
a gate of the first biasing transistor is directly coupled to a drain of the second biasing transistor; and
a resistor among the biasing resistors is directly coupled between a source of the first biasing transistor and the gate of the first biasing transistor.

18. The compensated amplifier circuit according to claim 17, wherein:
a gate of the second biasing transistor is directly coupled to the single supply voltage connection; and
a second resistor among the biasing resistors is directly coupled between a source of the second biasing transistor and the single supply voltage connection.

19. A compensated amplifier circuit comprising:
a transistor;
a compensation circuit comprising a biasing leg, the biasing leg comprising a stack of biasing transistors, a bias node along the stack of biasing transistors coupled to a terminal of the transistor, and biasing resistors coupled among the stack of biasing transistors; and
a single supply voltage connection coupled at one end of the biasing leg.

20. The compensated amplifier circuit according to claim 19, wherein:
the terminal of the transistor is a gate terminal of the transistor;
the single supply voltage connection comprises a connection for a negative voltage at the one end of the biasing leg; and
the compensated amplifier circuit further comprises a ground connection coupled at another end of the biasing leg.
